(19) United States
(12) Patent Application Publication
(10) Pub. No.: US 2011/0084708 A1
(43) Pub. Date: Apr. 14, 2011

(54) APPARATUS, DEVICES, SYSTEMS, KITS, AND METHODS OF MONITORING FOOD TREATING MEDIA

(76) Inventor: Steven Yu, Austin, TX (US)

(21) Appl. No.: 12/991,788

(22) PCT Filed: May 12, 2009
(86) PCT No.: PCT/US09/43604

§ 371 Date: Dec. 20, 2010

Related U.S. Application Data
(60) Provisional application No. 61/052,796, filed on May 13, 2008.

(51) Int. Cl. G01R 27/26; G01N 1/00; G01N 1/12

(52) U.S. Cl. 324/658; 73/864; 73/864.72

(57) ABSTRACT

An apparatus, system, and method regarding the monitoring of a fluid parameter are disclosed. More particularly, it relates to apparatus, systems, and methods of efficiently and economically monitoring the quality of a fluid, such as food treating media. An improved portable testing device may be in the form of a cartridge that is usable with a separate testing apparatus used to measure a parameter of the fluid carried on the sensing device. Included is a system and method that include a portable handheld device having a sensing device and a filter for protecting the sensing device from the fluid to be tested.

### BACKGROUND

The present description is directed to apparatus, systems, and methods regarding the monitoring of a fluid parameter. More particularly, it relates to apparatus, systems, and methods of efficiently and economically monitoring the quality of a fluid, such as food treating media.

Degradation of food treating media during food treating is widely recognized. Deep frying is one example of an extremely popular way of treating or preparing foods, and is typically a source of excessive levels of volatile and nonvolatile decomposition products, such as free fatty acids, total polar components (TPC), and acrylamides due primarily to overuse and/or overheating of the cooking oils, fats and carbohydrates. Excessive levels of these volatile and nonvolatile decomposition products have been associated with several kinds of diseases, such as hypertension, heart attacks, and diabetes. Free fatty acids, total polar components (TPC), and acrylamides tend to build-up in, for example, cooking oils and fats when subjected to, for example, oxidation and hydrolysis. Oxidation and/or hydrolysis tend to increase over prolonged periods of cooking oil use, especially when overheated.

Private and governmental efforts have sought to reduce excessive build-up of such decomposition products, such as free fatty acids and total polar components (TPC). Some efforts have led governments to impose restrictions on the amounts of decomposition products in cooking oils and foods.

Accordingly, efforts have been directed to monitoring the quality of cooking fats and oils for insuring compliance with such restrictions thereby maintaining a good oil quality during food treating. Compliance with higher standards may present safety, convenience and economic issues for establishments with existing equipment, such as deep frying equipment, trying to rapidly comply with newer regulations, standards, etc.

A common approach for preventing use of degraded cooking oil is to monitor and replace it. Monitoring quality of cooking oils typically relies upon workers, replacing the oil, based on their subjective judgments with respect to when the oil is degraded. Considering the impetus of the noted private and governmental efforts, there is a desire to minimize or remove subjective judgments of workers opining about the quality of the cooking oils. For example, cooking oils may be replaced if their color changes. However, for a worker determining at what point a change in color triggers replacement is problematic given the highly subjective nature of determining the adequacy of color changes. This issue is compounded given that there are various kinds of color changes that may arise from different kinds of cooking oils. Clearly, replacing cooking oil prematurely may result in wastage of otherwise costly and usable oil. On the other hand, using degraded oils containing excessive trans-fatty acids is unhealthy and may be in violation of applicable standards, rules, regulations, and laws.

Several known methods for evaluating oil quality use, e.g., dielectric constant measurements, visible and infrared spectroscopes, Fourier transform infrared (FTIR), column chromatography, and ultrasonic techniques. Absorptive membranes and surface acoustic waves (SAW) have also been used to measure oil quality. Many of the foregoing methods, while minimizing or reducing subjective judgments about oil quality, are, however, tedious, time consuming and subject to inaccuracies.

For example, known approaches for measuring cooking oil quality measure the dielectric constant, since there are known correlations between it and the levels of total polar compounds in the various kinds of cooking oils. Generally speaking there are several known types of devices for monitoring the quality of cooking oils by measuring its dielectric constant. One kind is an external permanent type; another type is an in-tank permanent sensor; and, still another type is an in-tank handheld sensor. While these known approaches function satisfactorily, there is nonetheless a desire to make improvements. For example, external permanent devices require relatively large amounts of hot cooking oil that have to be transferred for use with a relatively large pair of parallel plate electrodes for measurement of a fluid parameter (i.e., dielectric constant). Disadvantages associated with this approach include significant cleanup issues, potential of contamination of readings from particulates in the cooking oil, and relatively unsafe transport of large volumes of extremely hot cooking oil. In-tank monitoring approaches require sensors to be placed in the hot cooking oil of the fryer vat. Thus, they are prone to particulate contamination which minimizes the accuracies of quality reading. Portable sensors generally include a fixed electrode sensor that is inserted in the frying vat generally during the frying operation for significant time. This may be potentially unsafe because of splattering of hot cooking oil, thereby resulting in user burns. Additionally, these relatively expensive portable devices may be subject to damage resulting from accidental drops. Moreover, repeated usage of the exposed fixed sensors may create issues in regard to the electrodes being damaged during cleaning processes or to particulate build-up over prolonged use that may compromised the accuracy of their readings. Also, cleaning and particulate build-up issues may adversely affect the integrity of the cooking oil being monitored.

While there are successes using former approaches for monitoring cooking oils, none have done so in a manner that effectively, economically, and reliably monitors quality of fluids, such as cooking oils.

### SUMMARY

The present description is directed to a portable testing device for measuring a parameter of a fluid. The portable testing device comprises: a substrate carrying a sensing device for use in measuring a parameter of the fluid; and a filter in fluid filtering relationship to the sensing device.

The present description is directed to a single-use and portable testing device for measuring a parameter of a fluid. The portable testing device comprises: a substrate carrying a sensing device for use in measuring a parameter of the fluid; and a filter in fluid filtering relationship to the sensing device.

The present description is directed to a method comprising: providing a handheld testing apparatus including a sensing device for measuring a parameter of a fluid; and covering the sensing device with a filter having porosity for allowing the fluid to engage the sensing device but preventing particulate in the fluid from adversely affecting the sensing device.

The present description is directed to a method adapted for measuring a parameter of a testing fluid. The method comprises: filtering a sampled testing fluid immediately prior to the testing fluid substantially contacting a sensing device for measuring the parameter; heating the testing fluid prior to the fluid contacting the sensing device; and measuring the parameter of the fluid.

The present description is directed to a system that comprises: a portable testing device including a sensing device onto which a sample of the fluid is placed; and a testing apparatus including: a housing assembly configured for receiving the portable testing device; and a testing circuit electrically couplable to the sensing device for measuring a parameter of the fluid carried by the portable testing device.

The present description is directed to a system comprising: a handheld testing apparatus including a sensing device for measuring a parameter of a fluid; and a filter in combination with the sensing device, the filter having porosity for allowing the fluid to engage the sensing device but preventing particulate in the fluid from adversely affecting the sensing device

The present description is directed to a testing apparatus comprising: a housing assembly configured for receiving a portable testing device including a sensing device onto which a sample of the fluid is placed; and a testing circuit electrically couplable to the sensing device for measuring a parameter of the fluid carried by the portable testing device.

The present description is directed to a kit that comprises: at least one portable testing device; and a fluid sample holder comprising a holding body including a plurality of receptacles each sized and adapted to removably receive a portable testing device including a sensing device therein, the body includes an opening for allowing sample fluid to be introduced to the sensing element.

An aspect of the present description is a method, apparatus, and system for expeditiously monitoring quality of a food treating medium by measuring a quality parameter of the food treating medium.

An aspect of the present description is a method, apparatus, and system for monitoring quality of a food treating medium in a safe and reliable manner.

An aspect of the present description is a method, apparatus, and system for monitoring quality of a food treating medium in a safe and reliable manner by not requiring a user to stand over a vat of a heated medium for prolonged periods of time in order to obtain a reading.

An aspect of the present description is a method, apparatus, and system for achieving the foregoing by insuring that monitoring of the food treating medium is accurate and not compromised by particulates in the food treating medium.

An aspect of the present description is a method, apparatus, and system for monitoring quality of a food treating medium in a safe and reliable manner by utilizing micro quantities the food treating medium.

An aspect of the present description is a method, apparatus, and system for monitoring quality of a food treating medium through utilization of relatively low-cost and single-use disposable testing devices or cartridges.

An aspect of the present description is a method, apparatus, and system for monitoring quality of a food treating medium through utilization of relatively low-cost and repeatedly usable testing devices or cartridges.

An aspect of the present description is a method, apparatus, and system for monitoring quality of a food treating medium that is economical and simple.

The aspects described herein are merely a few of the several that can be achieved by using the present invention. The foregoing descriptions thereof do not suggest that the invention must only be utilized in a specific manner to attain the foregoing aspects.

### BRIEF DESCRIPTION OF THE DRAWINGS

These and other features and aspects of the present description will be more fully understood from the following detailed description of exemplary embodiments. It should be understood that the foregoing generalized descriptions and the following detailed descriptions are exemplary and are not restrictive of the present description.

FIG. 1 is a schematic perspective view of one aspect of a fluid quality monitoring system made according to one exemplary embodiment of the present description for monitoring quality of a food treating medium.

FIG. 2 is an enlarged exploded and schematic perspective view of one exemplary embodiment of a portable and single-use device usable in the system illustrated in FIG. 1.

FIG. 3 is a perspective view of the portable and single-use device illustrated in FIG. 2 but with a larger substrate.

FIG. 4 is a perspective view of the fluid monitoring device being received by a tester apparatus of the present description.

FIG. 5 is a simplified block diagram of a computer system utilizable in determining fluid quality in a fluid quality monitoring system depicted in FIG. 1.

FIG. 6 is a schematic view of an embodiment of a fluid sample acquisition device.

FIG. 7 is a schematic view of a process of acquiring samples using the sample acquisition device illustrated in FIG. 7

FIG. 8 is a simplified block diagram of a method that may be implemented by the fluid quality monitoring system.

FIG. 9 is a schematic planar view of another exemplary embodiment of the present description.

FIGS. 10A-C are schematic views of a sensing device and a filter as well as an illustration of covering the sensing device with the filter.

### DETAILED DESCRIPTION

According to the present description, provisions are made to improve upon the above noted drawbacks and shortcomings of determining quality of a fluid, such as a food treating medium, by providing highly reliable and low cost approaches of measuring parameters associated with the food treating medium.

The words “a,” “an,” and “the” are used interchangeably with “at least one” to mean one or more of the elements being described. By using words of orientation, such as “top,” “bottom,” “overlying,” “front,” and “back” and the like for the location of various elements in the disclosed articles, we refer to the relative position of an element with respect to a horizontally-disposed body portion. It is intended that the disclosed articles should have any particular orientation in space during or after their manufacture.

The present description is directed to a fluid quality monitoring system, apparatus, and method that are related to monitoring quality of a food treating media, such as cooking oil. Also, the present description is directed to a sample acquisition apparatus for use in monitoring a plurality of cooking oils.

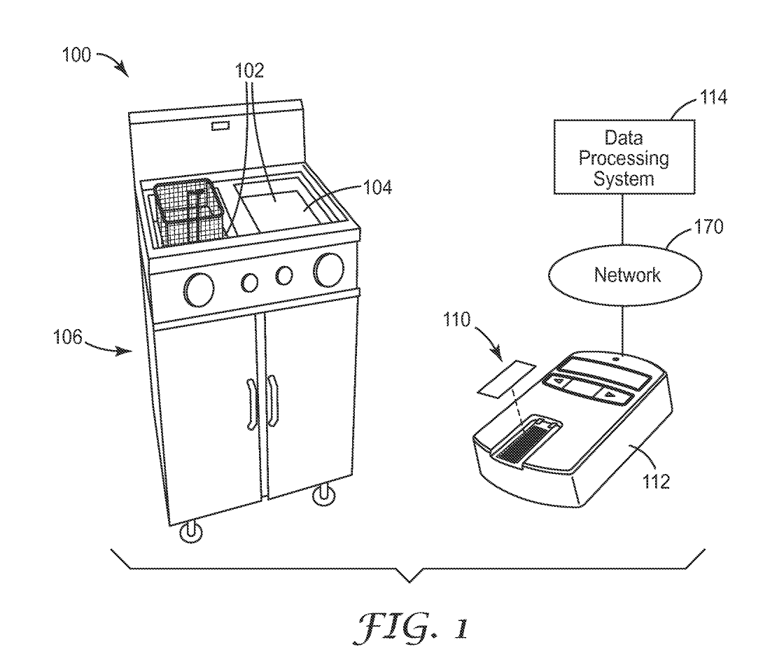

Reference is made to FIGS. 1-8 for illustrating one exemplary embodiment of a fluid quality monitoring system 100 that is operable for monitoring the quality of a fluid 102, such as a food treating media 102. The food treating media 102 contemplated may include, but are not limited to, cooking oils, fats, water, sauce, or other medium. The cooking oils and fats may be vegetable based, animal based, synthetic, or blends thereof and are generally considered to be edible.

FIG. 1 is a schematic view of a fluid quality monitoring system 100 for monitoring the quality of a food treating media 102, such as cooking oil 102, that may be used in a vat 104 of a deep fryer 106 or the like for treating food. The quality monitoring system 100 is operable for implementing a process of determining at least a quality parameter of the cooking oil 102 in order to determine the latter's quality or conversely its relative deterioration. In particular, the fluid quality monitoring system monitors at least a quality parameter of the fluid, such as the capacitance value of the cooking oil. Capacitance values provide reliable correlations to media quality and, in particular, to total polar compounds (TPC) that are often found in many food treating media, such as cooking oils. By measuring changes in the capacitance values of the cooking oil, as will be explained, the present quality monitoring system determines quality of the cooking oil as a function of its TPC (%) levels. These parameter values typically change over time. Accordingly, several readings of the cooking oil are typically performed to determine if it is unsatisfactory or not. While the illustrated exemplary embodiment is described in the context of monitoring the capacitance value of the cooking oil, it will be appreciated that the present description is broadly capable of monitoring one or more other fluid parameters. For example, the fluid parameters capable of being monitored exclusively or in combination include, but not be limited to, free fatty acid levels, fluorescence, viscosity, and/or conductivity.

The fluid quality monitoring system 100 includes a portable and single-use testing cartridge, apparatus or device 110, into which a sample of cooking oil may be deposited for testing as will be described; a testing apparatus 112 that operates, in combination, with the portable testing device 110, and a data processing system 114 for processing the data regarding the fluid parameter being monitored.

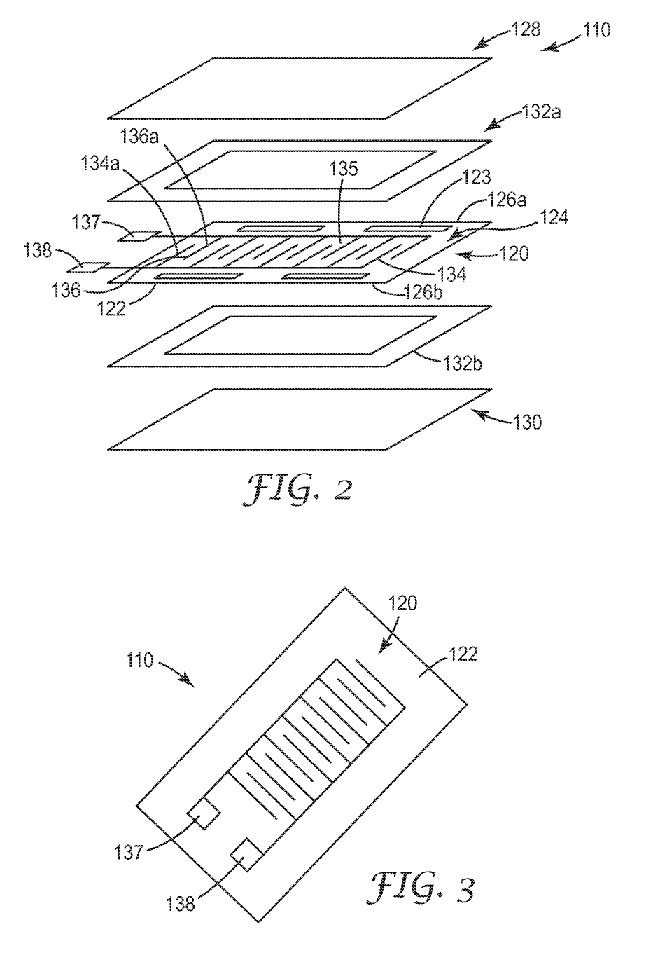

FIGS. 2-5 illustrate one exemplary embodiment of a single-use and portable testing cartridge, apparatus, or device 110. Essentially, the portable testing device 110 is operable for use in accurately and reliably determining a quality parameter value of a fluid sample carried thereby. In one exemplary embodiment, the parameter value being tested for may be the capacitance value of the cooking fluid. Capacitance values are related to quality values correlated to fluid cooking media deterioration or conversely quality. The portable testing devices made in accordance with the present description may be of a disposable nature or may be reusable for repeated measurements. The portable testing devices may include a variety of sizes and shapes and include, but are not limited to, strips or elements.

The exemplary embodiment of the single-use and portable testing device 110 illustrated in FIGS. 1-4 may be self-contained in a single integral unit that has single-use characteristics in that it is disposable. As noted, the portable testing device 110 may be adapted to handle relatively small amounts of fluid (e.g. micro liters) deposited thereon. For example, for static measurements, about 5 micro liters may be deposited on the portable testing device 110. As such, this is highly advantageous since relatively small amounts of sampled fluid are easier and safer to obtain and handle compared to larger samples typically used in known monitoring approaches. Clearly, the present description envisions other sample volumes and the foregoing values are not to be considered limiting.

Essentially, the testing cartridge or device 110 may be a generally planar and flexible element that is self-supporting and carries a sensing device 120. The sensing device 120 may be a substrate 122 carrying an interdigital capacitor element 124, on one major surface 126a thereof. The interdigital capacitor element is operable with the fluid to be tested for measuring a quality parameter, capacitance value, of such fluid; a filter 128 supported by the substrate 122 in overlying and/or juxtaposed relationship to at least a portion of the interdigital capacitor element 124; and an absorbent pad 130 in generally coextensive relationship with a major surface 126b of the substrate 122 that is opposing to the major surface 126a carrying the microcircuit. A pair of adhesive frames 132a, 132b may be provided in order to better join the filter membrane and the oil absorbing pad to the substrate 122. The filter may be supported or connected by the substrate or some other structure, so as to be in overlying and/or juxtaposed relationship to the sensing device 120.

The substrate 122 may be made of any suitable material that may carry electrical circuit elements thereon without materially adversely affecting electrical measurements and stable enough to withstand temperatures of the sampled fluid, as well as chemical reactions to the cooking oil or the filter. In addition, the substrate 122 material may be made so as to be easily formed as by molding, lasing, or lithographic etching for forming the interdigital capacitor elements. For example, the substrate 122 may be made of a wide variety of materials, such as, but not limited to polyester, polyethylene terephthalate (PET), polytetrafluorethylene or polytetrafluorethene (PTFE), and other similar materials. In the exemplary embodiment, the substrate 122 may be flexible and thin layer. The substrate 122 may have a thickness in a range of from about 1 mil to about 5 mils. More typically, the thickness of the substrate 122 may be in the range of from about 2 mils to about 3 mils. The foregoing values should not, however, be considered limiting. Also, while the substrate 122 is flexible, the present description envisions that that the substrate may be rigid as well.

The substrate 122 and for that matter the portable testing device 110 may include one or more gaseous fluid venting structures 123 for inhibiting gaseous fluids (e.g., air) from being trapped between it and the filter 128. The trapping may occur in response to the sampling fluid being deposited on the filter and flowing to the sensing element. In the illustrated exemplary embodiment, one or more gaseous fluid venting structures 123 include mechanically punched gaseous fluid venting slots 123 or other types of openings 123 in the substrate 122 for allowing passage of trapped gaseous fluid from one side to an opposing side. Other venting structures for avoiding trapping gaseous fluids are envisioned. For example, other venting structures include, but are not limited to perforations in the filter. The gaseous fluid venting slots 123 may range in size from about 1 mm to about 3 mm. The foregoing values should not, however, be considered limiting.

As depicted, the interdigital capacitor element 124 on the substrate is comprised of a spaced pair of electrodes 134, 136 that are separated by a relatively small gap or micro-cavity 135 therebetween for facilitating measuring the capacitance of a cooking fluid dropped into the cavity and covering the electrodes 134, 136. The electrodes 134, 136 are in spaced and generally coplanar alignment and provide for accurate and reliable readings. The gap 135 may be sized for receiving relatively small amounts of cooking oil (e.g., 1-5 micro liters). The sample cooking oil will be received and cover the electrodes for testing purposes. While the present exemplary embodiment describes a pattern of conductive elements fixed on the substrate that facilitate a capacitive measurement of cooking oil, the present description may have other patterns and sizes.

In the present exemplary embodiment, the interdigital electrodes 134, 136 may be formed from thickened portions of the substrate that are coated, such as by dip coating, chemical vapor deposition, and other similar process with a conductive material. The conductive materials may include, but are not limited to, gold, silver, aluminum, platinum, tin, carbon, noble metals, or may be made of a composite of materials, and combinations thereof that are effective for performing in the manner desired including being able to measure the capacitance value of the food treating medium. The thickness of the trace conductive materials, such as gold may be in the order of about 50 nm to 1000 nm. Other suitable dimensions may be used. The electrodes 134, 136 each comprise interdigital fingers or teeth 134a, 136a; respectively. In the illustrated exemplary embodiment, the interdigital fingers or teeth 134a, 136a may have a pitch in the order of about 20 microns to about 100 microns. More typically, the pitch of the electrodes may be about 20 to 40 microns. In one illustrated embodiment, the pitch may be about 20 microns. The thickness of the coating may vary. The foregoing values should not, however, be considered limiting.

The gap 135 is formed between the opposing portions of the interdigital fingers 134a, 136a of the electrodes as is, for example, illustrated in FIG. 2. Each of the interdigital electrodes 134, 136 is connected by leads to contact pads 138, 137; respectively. The contact pads 137, 138 are adapted to be electrically coupled to electrodes 140 of the testing apparatus 112 for measuring the capacitance of the sampled cooking oil as will be explained. For example, the interdigital electrodes are made of a conducting material and are additionally coated with a coating material that will provide oleophobic and/or hydrophobic properties and yet not materially interfere with the electrical measurements. The contact pads 137, 138 of the portable testing device 110 extend longitudinally from the substrate as is illustrated in FIG. 2. Alternatively, the contact pads 137, 138 and their leads may be supported on an extension of the substrate as illustrated in FIG. 3. When supported on the substrate one or both contact surfaces of the pads may be exposed for cooperation with the testing apparatus 112. In this manner, either major surface of the portable testing device may be mounted on the testing apparatus. Alternatively, the contact pads need not be included for measurement purposes.

The filter 128 may be filter membrane 128. In this embodiment, the filter 128 may be a non-woven polypropylene filter membrane 128 that is able to separate particulates from the cooking oil without changing the monitored characteristics of the oil that had been filtered. While a filter membrane may be used, other kinds of filters are contemplated, and include but are not limited to other suitable microfluidic filters. The filter membrane 128 may be constructed from a material having a porosity to block particulates in the sampled cooking oil from the electrodes thereby preventing faulty readings, as well as potential for adversely affecting the electrodes. The filter membrane 128 may be constructed from a variety of materials, such as from a group consisting of non-woven polypropylene, filter paper, and ceramic filter, or combinations thereof. The filter membrane 128 may have porosity typically ranging from about 1 micron to about 50 microns, and, more typically, from about 3.5 to 10 microns. The filter membrane 128 may be relatively thin, such as in the order of about from about 1 mil to about 2 mils. The foregoing values should not, however, be considered limiting. In one illustrated exemplary embodiment, the filter membrane 128 may have a pore size that is about 10 microns and a thickness that is about 4.5 mils. The latter filter membrane material with the foregoing thickness and pore size may be commercially available from 3M Corporation, St. Paul, Minn. The filter membrane may be cut to the appropriate size to cover the interdigital electrodes leaving the bond pads uncovered for external electrical connection. Instead of being in overlying and juxtaposed relationship, it will be appreciated that the filter may be placed laterally, in juxtaposed relationship, to the sensing device. In such a case, a filter would filter the fluid being delivered, such as by a fluid channel or the like to the sensing device.

The oil absorbent pad 130 may be adhesively coupled to the flex circuit substrate by the adhesive frame 132b. The oil absorbent pad 130 may be made from a variety of materials, such as but not limited to non-woven polypropylene, paper, cotton, or the like and combinations thereof. In exemplary embodiment the absorbent pad that include, but are not limited to non-woven material, filter paper or the like. For example, such material may be commercially available from 3M Corporation, St. Paul, Minn. The oil absorbent pad 130 may have a thickness in the range of from about 2 mils to about 5 mils. The foregoing values should not be considered limiting. While one exemplary embodiment includes the oil absorbent pad 130, it will be appreciated that the portable testing device 110 may not include such an oil absorbent pad although such pad provides significant benefits in terms of maintaining a clean environment. The absorbing pad 130 allows rapid oil flow in vertical direction through venting slots.

The adhesive films or frames 132a, 132b may be a hot melt adhesive, such as a non-woven polyester. In one exemplary embodiment, such an adhesive may be commercially available from Bostik Division of USM Corp., Emhart Industries Inc., Boston, Mass. under the trade name Bostik PE120. The adhesive films may be cut out into a frame as illustrated in FIG. 1, and placed between the microcircuit and the substrate. The elements of the portable testing device forming the portable testing device 110 may be joined together by heat and pressure, such as roll lamination between 140° C. to 150° C. for about 20 seconds on a hot plate. Of course, other suitable approaches are contemplated for bonding or joining the elements together as illustrated. The hot melt adhesive has good oil resistance and adhered to the polyester circuit even after two hours in hot oil at 80° C. While adhesive frames are described, it will be appreciated that other suitable approaches of joining the elements together may be utilized, such as, but not limited to sonic welding, epoxy, or other adhesive materials resistant to oil. Examples of suitable layer thicknesses for adhesive frames or films 132a, 132b range from about 0.1 mil to about 0.5 mil, with more typical thicknesses ranging from about 0.2 mil to about 0.3 mil. While the exemplary embodiment describes adhesive layers or frames for joining the layer together, the present description envisions that other bonding approaches may be used, such as sonic welding. The foregoing values should not, however, be considered limiting.

In the illustrated exemplary embodiment, the portable testing device 110 may have a generally thin and rectangular shape. In one embodiment, the portable testing device 110 measures about 5 inches (0.127 meters) in length and 3 inches (0.0762 meters) in width, but other shapes and sizes are envisioned. Also, the foregoing values should not be considered limiting. While a single testing device 110 is depicted, it will be understood that a plurality of such devices may be joined together by, for example, separable and tearable portions (not shown). A plurality of testing devices may be connected together in a longitudinally extending strip that may be wound in a roll (not shown).

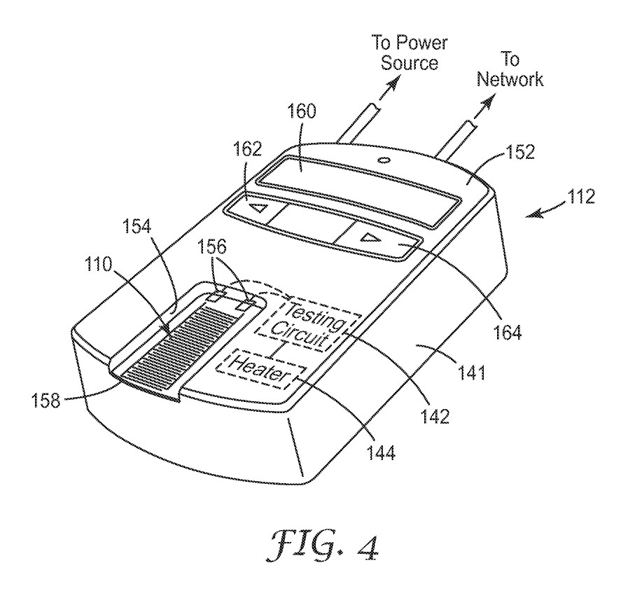

The testing apparatus 112 is illustrated in FIG. 4 and has having a generally parallelepiped enclosure or housing assembly 141. The housing assembly 141 may be made of any suitable materials, such as a thermoplastic material, for example, polycarbonate, ABS or the like. The housing assembly 141 may have a variety of configurations and sizes. The testing apparatus 112 may include a capacitance measuring testing circuit 142 for measuring the capacitance of the cooking oil cooperating with the interdigital electrodes on the portable testing device 110, and a heating element 144, such as a heating block 144 that may be under the control of the data processing system 114. The capacitance measuring testing circuit 142 may be any suitable type that in a known manner is able to derive signals representative of the capacitance of the cooking oil between the interdigital electrodes. The capacitance values obtained will be related to the total polar compounds of the cooking oil being tested. The electrodes form with the sampled oil a capacitive measuring element whose capacitance varies as a function of the TPC of the oil. When the oil is degraded, the quantity of TPC present therein increases and causes an increase in its capacitance value. Thus, by measuring changes in the capacitance of the capacitive measuring element, the degree of quality and/or degradation of the sampled cooking oil may be determined.

Referring back to the housing assembly 141 it includes a front cover assembly 152 that may include at least one cartridge recess 154. The cartridge recess 154 is sized and adapted to removably receive the portable testing devices 110 for testing in accordance with the present description. In this regard, the capacitance measuring testing circuit 142 includes a pair of testing electrodes 156. The testing electrodes 156 are adapted to electrically cooperate with the contact pads 137, 138. A user may hold the portable testing device 110 against the housing assembly 141 so as to ensure proper contact. The heating block 144 is operated to heat the surface 158 to a temperature which insures that the fluid being carried by the portable testing device 110 maintains its liquid characteristics so as to flow to the interdigital electrodes. The heating block 144 may be under control of the data processing system 114. A suitable power source provides power to the testing apparatus 112. The front cover assembly 152 may be formed with a suitable display 160 for providing information that is relevant for the process of the present description. Other types of output may be provided for supplying the information. The present description is not limited to the foregoing types of information to be displayed or the kinds of output devices. The display 160 may include liquid crystal displays (LCD's), light-emitting diodes (LED's) or similar information output devices. Included on the front cover assembly 152 is at least a pair of control buttons 162, 164 that allow a user to control the process as well as the information displayed as will be explained. The finger actuated switch element 162 may be depressed by a user from its normally non-operative state to an operative state for commencing a testing mode.

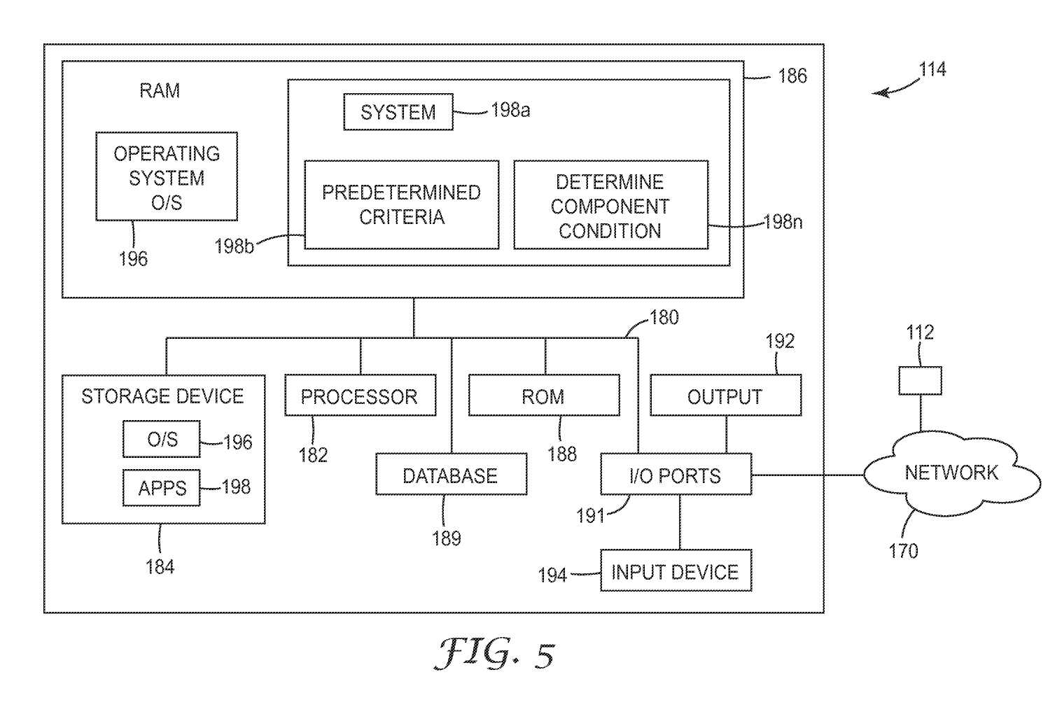

Reference is made to FIG. 5. As noted, one or more testing apparatus 112 is networked to the data processing system 114, through a network 170 to an electronically programmable device 180, for evaluating the quality of the cooking oil. Typically, the cooking oil may be monitored until replacement. The network 170 may include, without limitation, a local-area network (LAN), a wide-area network (WAN), the internet, or a wireless network, such as a wireless local area network (WLAN). The electronically programmable device 180, may be a server computer, client computer, minicomputer, midrange computer, PC based server, mainframe computer, handheld, laptop computer, programmable logic device, or other suitable device. In one exemplary embodiment, a commercially available laptop computer system may be used. The laptop computer includes functionalities that enable the determination of cooking oil quality and the ability to track the quality of several batches as the cooking oil. For example, cooking oil replacement may occur if the total polar compounds exceed a threshold value that may have been established by a private or government entity that is interested in monitoring quality of cooking oil, especially after prolonged usage.

With continued reference to FIG. 5, the laptop computer system may include at least one system interconnect bus 180 to which various components are coupled and communicate with each other. Coupled to the system interconnect bus 180 is at least a single processor unit 182, storage device 184, memory such as random access memory (RAM) 186, read only memory (ROM) 188, a relational database management system (DBMS) 189, and input/output (I/O) ports 191. The relational database is a computer database management system 189 controlling the storing, updating, and retrieving of data to database files for use in tracking usage of components against one or more predetermined criteria. The database files contain all relevant information pertaining to the operational parameters of the cooking oils and fats. Furthermore, one or more output devices 192, such as the LCD display, as well as one or more user interface input devices 194, such as a keyboard and/or pointing device is respectively coupled to the I/O ports 191. The I/O port 191 typically includes various controllers (not shown) for each input device 194, such as a keyboard, mouse, joystick, and the like, as well as the output device 192, such as an Ethernet network adapter, infrared device and display (not shown). The processor 182 controls the input device 194 which provides a user interface for allowing a user to access information, such as usage history of components being tracked. The processor unit 182 may be any suitable processor and sends and receives instructions and data to and from each of the computer system's components that are coupled to the system interconnect bus 180 to perform system operations based upon the requirements of the computer system's operating system (OS) 196, and other specialized application programs 198a-198n (collectively 198).

The ROM 188 typically controls basic hardware operations. The storage device 184 may be a permanent storage medium, such as a hard disk, CD-ROM, tape, or the like, which stores the operating system 196 and the specialized applications programs 198. The RAM 186 is volatile memory. The contents of the RAM 186 may be retrieved from the storage device 184 as required. Illustratively, the RAM 186 is shown with the operating system 196 and application programs 198 concurrently stored therein. The program codes of the operating system 196 and/or application programs 198 may be sent to the RAM 186 for temporary storage and subsequent execution by the processor 182. Additionally, the RAM 186 is capable of storing files from the operating system 196, as well as files from one or more application programs.

An information retrieval and processing system application program(s) 198a is one typically utilized for controlling operations of the fluid quality monitoring system 100 including the data processing system including the database 189. Provision is made for predetermined criteria application 198b which may be used to establish the values for TPC for different oils for use in comparing to the tested oils against those values which were established by the rules and regulations of, for example, government, private entities, and the like. A determine component condition application 198n of the present description enables determining the conditions of cooking oil quality following monitoring as described above. A report generating application may be provided that may generate reports containing a variety of data in different reporting formats tailored for purposes including those described below. The latter application may be included in the determining component condition application or may be provided separately. The reports may be generated to allow users, supervisors, and health professionals to access the history and status of cooking oil quality as well as other information and history deemed relevant.

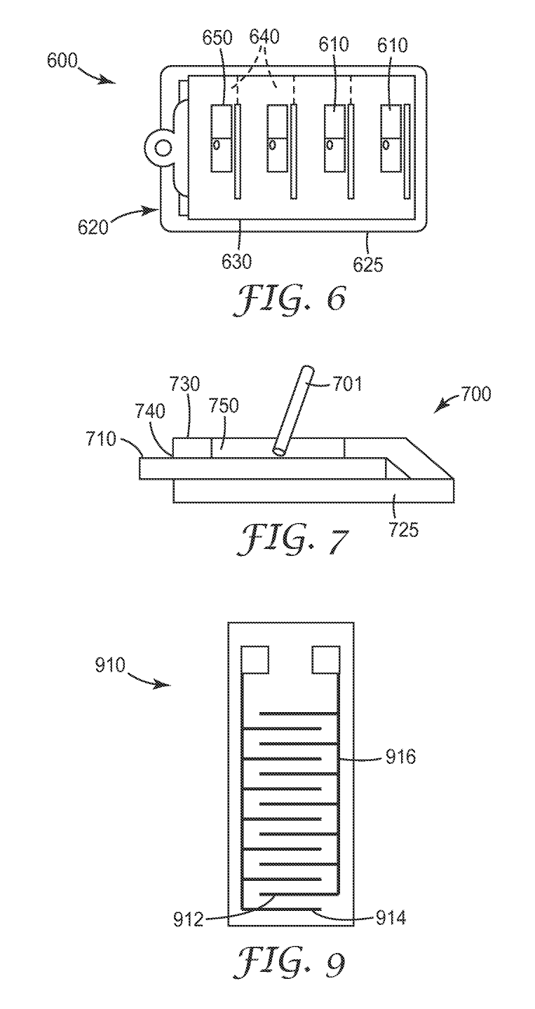

FIG. 6 illustrates schematically one version of a sample acquisition kit apparatus 600 adapted to be used by the present description for removably receiving a plurality of testing devices 610 so as to facilitate transportation and testing. The portable testing devices 610 for use in combination with the sampling acquisition kit apparatus 600 may be similar to those described above. The sampling acquisition kit apparatus 600 enables a user to insert and remove each of the several ones of the testing cartridges in an easy and convenient manner. The sampling acquisition kit apparatus 600 in the illustrated exemplary embodiment may be a fluid sample holder 620 having a body 625 and a cover 630 that are attached together in such a manner to form separate receptacles 640 or pouches 640 for slidably receiving separate ones of the portable testing devices 610. Openings or windows 650 are formed in the cover 630 for allowing samples of the cooking oil to be deposited on registered filters of the testing devices 610. The fluid holder member 620 may be a clipboard for facilitating carrying the samples from the cooking oil vat to the testing apparatus 112. While in the illustrated exemplary embodiment, the cover is joined to the base, such need not be the case, since the cover may be a separate member in the form of a plate or the like, wherein windows in the cover would be placed in registration with the portable testing devices.

In FIG. 7, a pipette 701 may be used for collecting a cooking oil sample for it one the filter membrane of a portable testing device 710 while being held in a receptacle 740 formed between the base 725 and cover 730 of the sampling acquisition apparatus 700. The sample acquisition device 700 may be like the previously described one in FIG. 6. Of course, other constructions are envisioned for use removably holding the portable testing devices 710. While a pipette 701 may be utilized for introducing the sampled fluid through a window 750, the present description is not limited to this approach. Other suitable sampling devices may be used. An advantage of the foregoing approach is that a user need not spend significant time trying to get a sample that is adequate for testing or holding a testing apparatus in a vat of hot cooking oil.

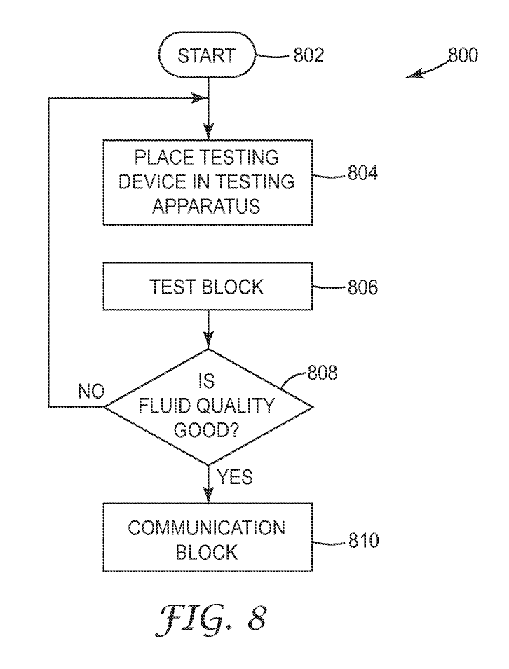

Reference is made to FIG. 8 for illustrating one exemplary embodiment of a fluid quality monitoring process 800 that may be implemented by the component fluid quality monitoring system 100. The fluid quality monitoring process 800 commences in a Start block 802 wherein a user presses the control button 162 (FIG.4) to start the process. In the process 800, the Place Testing Device in the Testing Apparatus block 804, one testing device 110 may be placed in the cartridge recess so that the contact pads engage the electrodes of the testing apparatus 112. A sample of the cooking oil may be deposited by a user on the filter membrane 128. Alternatively, the cooking oil may have been placed on the filter membrane prior to placing the portable testing device on the housing assembly. Application of the cooking oil may be achieved by a pipette 701 as is illustrated in FIG. 7. As noted, the heating block 144 (FIG.4) may be activated, as noted, to heat the surface to a temperature sufficient to ensure that any cooking oil deposited on the filter membrane freely flows to the sensing device. In a Test block 806, a capacitance reading of the cooking oil carried by and between the interdigital electrodes is taken. The data processing system may be able to determine the capacitance of the cooking oil sampled and determine its value. The process 800 then proceeds to Is Fluid Quality Good decision block 808 in which a determination is made based on comparing the read value with the known TPC values representative of satisfactory (i.e., good) or unsatisfactory quality. If the cooking oil is unsatisfactory then the process 800 may notify the user of the present state of the cooking oil such as through information displayed on the display 160 (FIG.4). If the determination is Yes, then the cooking oil is unsatisfactory and may be replaced. If the determination is No, then the cooking oil may be reused. Thereafter, the results are communicated back to the user such as though display information. According to the data processing system, the information of the cooking oil that is reusable may be logged into the database for future use. Reports may be generated communicated in the Communication block 810 under control of the report generating application.

FIG. 9 illustrates a portable testing device 910 that is similar to the portable testing devices described above. The interdigital pair of electrodes 912, 914 may be made of gold, for example, and have a protective coating 916 which may have hydrophobic and/or oleophobic properties to the fluid treating medium to be tested. In one exemplary embodiment, the protective coating 916 may be a material that greatly enhances removal of cooking oil. The present description envisions a variety of known protective coating materials for providing the hydrophobic and/or oleophobic properties. Materials that may be used in such situations include, but are not limited to, silicone coatings, and acrylate polymers. In one exemplary embodiment, such a coating may be made from a fluorinated coating. The coating may be applied by known techniques suitable for joining the coating to the conductive material, such as by, but not limited to, dip coating and chemical vapor deposition or the like. The coating may be a monolayer that is sufficiently thick to provide for the hydrophobic and/or oleophobic properties and yet not materially interfere with electrical conductivity so as to, for example, adversely materially affect the accuracy of the capacitance readings.

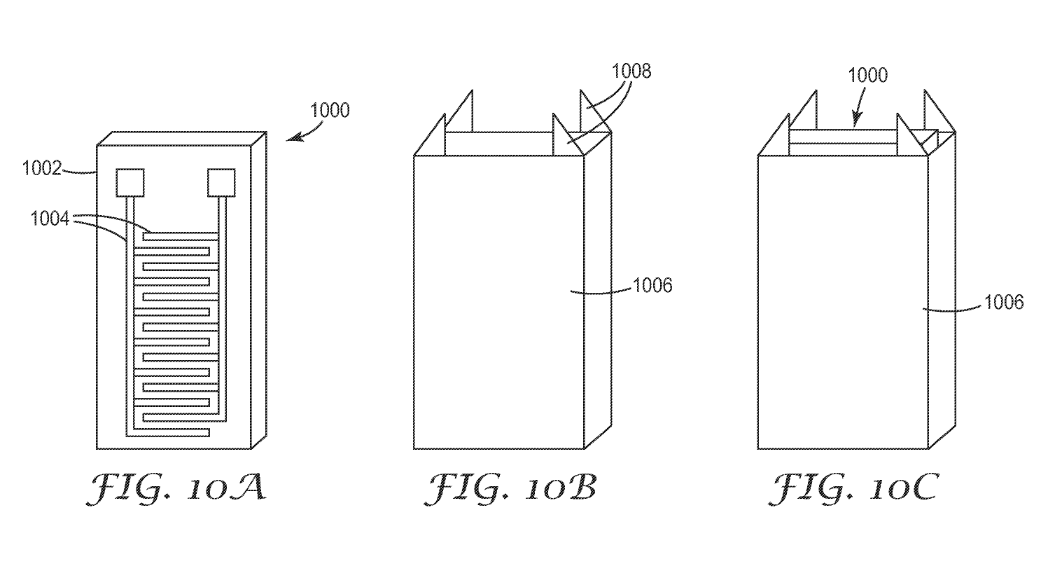

FIGS. 10A-C are schematic views of a sensing device and a filter as well as an illustration of covering the sensing device with the filter. A sensing device 1000 includes a body or substrate 1002 that includes an interdigital capacitor element 1004 mounted thereon. The sensing device 1000 may be like that described above as a cartridge. Alternatively, the sensing device may be connected to a shaft (not shown) of a handheld testing device or apparatus of the kind dipped into cooking oil for purposes of conducting tests of the kind noted above. A filter 1006 may be provided so as to be placed in covering and juxtaposed relationship to the sensing device. The filter 1006 may have a construction as illustrated, such as a parallelepiped which is sized and shaped to receive through an opening the sensing device 1000 as illustrated in FIG. 10C. The present description contemplates a variety of sizes and shapes for the filter for purposes of covering the sensing device for filtering purposes. Such variations include, but are not limited to, a flexible bag, pouch, or similar type flexible container having an opening for receiving the sensing device 1000. The filter 1006 may be made of a material that withstands high temperatures, such as but not limited to 180° C. Typically, such materials include, but are not limited to, polymeric materials, polyamides, polytetrafluorethylene or polytetrafluorethene (PTFE), and other like materials as well as combinations thereof that would not break down in high temperatures and at least provide the porosity noted above. As noted, the porosity of the filter 1006 is such that it allows the fluid, to be tested, to pass therethrough, but prevent or block undesired particulates in the fluid from passing to the interdigital capacitor element 1004 and shorting or otherwise damaging the electrodes, or inhibiting capacitor readings. In this regard, the porosity may be the same as with the filter described above. Of course, the porosity values are not limiting.

In the present illustrated exemplary embodiment, the filter 1006 has one or more attaching members 1008, which are schematically represented. The attaching members 1008 may take a variety of forms that may coupled to the filter. The attaching members 1008 may include one or more of several kinds of attaching devices, such as foldable clamps 1008 that would be folded about the sensing device 1000 to clamp the latter to the sensing device 1000. The foldable clamps 1008 may be suitably attached to the filter 1006. Besides clamps the attaching member(s) may be in the form of a string that could wrap around the sensing device 1000 or to a rod (not shown) supporting the sensing device to a handheld tool apparatus. The attaching members 1008 may be in the form of adhesive strips (not shown) or the like that would serve to be secured to the sensing device 1000 or to another support for supporting the sensing device (e.g., rod). It may be desired that the filter 1006 may partially enclose the sensing device, as seen in FIG. 10C or completely enclose or envelope the sensing device 1000.

The above embodiments have been described as being accomplished in a particular sequence, it will be appreciated that such sequences of the operations may change and still remain within the scope of the invention. For example, an illustrated embodiment discusses one set of testing protocols. It will be appreciated that other testing procedures may be performed to conduct testing of fluid quality. Also, other procedures may be added.

This invention may take on various modifications and alterations without departing from the spirit and scope. Accordingly, this invention is not limited to the above-described embodiments, but is to be controlled by limitations set forth in the following claims and any equivalents thereof. This invention also may be suitably practiced in the absence of any element not specifically disclosed herein.

What is claimed is:

1. A portable testing device for measuring a parameter of a fluid, the portable testing device comprises: a substrate carrying a sensing device for use in measuring a parameter of the fluid; and a filter in fluid filtering relation to the sensing device.

2. The testing device of claim 1, wherein the filter is in at least one of a juxtaposed and/or overlying relationship to the sensing device.

3. The testing device of claim 1, wherein the substrate is a thin strip having a thickness in the range of from about 1 mil to 5 mils.

4. The testing device of claim 1, further including one or more structures for inhibiting a gaseous fluid from being trapped between the filter and the sensing device.

5. The testing device of claim 4, wherein the one or more structures include an opening for allowing passage of a trapped gaseous fluid from one side of substrate to an opposing side of the substrate.

6. The testing device of claim 1, wherein the sensing device includes interdigital electrodes.

7. The testing device of claim 1, further including an absorbent element joined to the substrate on a major surface opposing the filter, wherein the absorbent material is made from a material from a group consisting of non-woven polypropylene, paper, cotton and combinations thereof.

8. The testing device of claim 6, wherein the interdigital electrodes are made of a material from a group consisting of gold, silver, aluminum, platinum, noble metals, tin, carbon, conductive composite materials, and combinations thereof.

9. The testing device of claim 1, wherein the substrate is made from a material that does not materially affect electrical measurements, is stable enough to withstand temperatures of the fluid, as well as resists chemical reactions to the sampled fluid, and wherein the substrate is made from a material from a group consisting of polyester, polyethylene terephthalate (PET), polytetrafluorethylene, and, polytetrafluorethene.

10. The testing device of claim 1, wherein the filter is made from a material from a group consisting of non-woven polypropylene, filter paper and ceramic filter material.

11. The testing device of claim 1, wherein the filter has porosity for allowing the fluid to engage the sensing device but preventing particulate in the fluid from adversely affecting the sensing device, wherein the filter has porosity in a range of from about 1 micron to about 50 microns.

12. The apparatus of claim 1, further including contact pads that connect with the sensing device.

13. A system comprises: a portable testing device including a sensing device onto which a sample of fluid is placed; and
a testing apparatus including: a housing assembly configured for receiving the portable testing device, and a testing circuit electrically couplable to the sensing device for measuring a parameter of the fluid carried by the portable testing device, and wherein the portable testing device comprises: a substrate carrying a sensing device for use in measuring a parameter of the fluid; and a filter in fluid filtering relationship to the sensing device.

14. The system of claim 13, wherein the testing circuit is for measuring the capacitance of fluid in the sensing device.

15. A testing apparatus comprising: a housing assembly configured for receiving a portable testing device including a sensing device onto which a sample of fluid is placed; and a testing circuit electrically couplable to the sensing device for measuring a parameter of the fluid carried by the portable testing device.
